(19) United States
(12) Patent Application Publication
(10) Pub. No.: US 2026/0136567 A1
(43) Pub. Date: May 14, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Hsing-Chih Lin, Tainan City (TW); Meng-Hsien Lin, Tainan City (TW); Ko Chun Liu, Toufen Township (TW); Jaio-Wei Wang, Kaohsiung City (TW); Jen-Cheng Liu, Hsin-Chu City (TW)

(21) Appl. No.: 18/942,981

(22) Filed: Nov. 11, 2024

(51) Int. Cl. H01L 23/522; H01L 27/06

(52) U.S. Cl. CPC H10D 1/042; H10D 1/716; H10D 88/00; H10W 20/496

(57) ABSTRACT

Various embodiments of the present disclosure are directed to an integrated circuit (IC) in which a capacitor (e.g., a three-dimensional (3D) metal-insulator-metal (MIM) capacitor or the like) has a trench segment landing on a capacitor-bottom via. The capacitor-bottom via extends from the trench segment to a capacitor-bottom wire that underlies the capacitor to electrically couple the capacitor to the capacitor-bottom wire. The trench segment is one of a plurality of trench segments of the capacitor, and an additional trench segment of the plurality of trench segments is spaced from the capacitor-bottom via and a wire level at which the capacitor-bottom wire is located. This frees a portion of the wire level directly under the additional trench segment for routing of signals unrelated to the capacitor.

### BACKGROUND

Integrated circuits (ICs) are formed on semiconductor dies comprising millions or billions of transistors. The transistors are configured to act as switches and/or to produce power gains so as to enable logical functionality. ICs also comprise passive devices used to control gains, time constants, and other IC characteristics. One type of passive device is a three-dimensional (3D) metal-insulator-metal (MIM) capacitor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated circuit (IC) comprising a capacitor with a trench segment landing on a capacitor-bottom via.

FIG. 2 illustrates a cross-sectional view of some embodiments of the IC of FIG. 1 in which the capacitor and a dielectric structure surrounding the capacitor have additional detail.

FIG. 3A illustrates a top layout view of some embodiments of the capacitor of FIG. 2.

FIGS. 3B-3G illustrate top layout views of some alternative embodiments of the capacitor of FIG. 2.

FIG. 4 illustrates an additional cross-sectional view of some embodiments of the IC of FIG. 2 and/or FIG. 3A.

FIGS. 5A-5F illustrate cross-sectional views of some alternative embodiments of the IC of FIG. 2 in which the capacitor and surrounding structure are varied.

FIG. 6 illustrates a cross-sectional view of some embodiments of the IC of FIG. 2 in which the IC further includes extended vias, transistors, and multiple circuit regions.

FIGS. 7-21 illustrate a series of cross-sectional views of some embodiments of an IC comprising a capacitor with a trench segment landing on a capacitor-bottom via.

FIG. 22 illustrates a block diagram of some embodiments of the method of FIGS. 7-21.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Further, numerical designations (e.g., first, second, third, etc.) may be used for clarity to distinguish between components of the same type. However, it is to be appreciated that the numerical designation may vary depending upon context. For example, a component referred to as third in one figure, may be referred to as fourth in another figure if another component of the same type already has the designation of third.

An integrated circuit (IC) may comprise an interconnect structure overlying a substrate, and a three-dimensional (3D) metal-insulator-metal (MIM) capacitor surrounded by the interconnect structure. The interconnect structure comprises a plurality of wires and a plurality of vias respectively grouped into a plurality of wire levels and a plurality of vias that are alternatingly stacked away from the substrate. The 3D MIM capacitor comprises a plurality of trench segments that all protrude towards the substrate and that all land on a common wire of the interconnect structure, thereby electrically coupling a bottom electrode of the 3D MIM capacitor to the common wire at each of the plurality of trench segments.

Being that a 3D MIM capacitor can be large relative to other devices and structures of the IC, the common wire on which the plurality of trench segments land can be relatively large. As such, a relatively large portion of the wire level at which the common wire is located (e.g., a portion of the wire level directly under the 3D MIM capacitor) is unavailable for signal routing. This reduces routing flexibility. Further, as ICs continue to get smaller and smaller, this lack of routing flexibility will become more and more of a challenge because wires and vias have minimum spacings and sizes that do not change with the scaling down of ICs.

Various embodiments of the present disclosure are directed to an IC in which a capacitor (e.g., a 3D MIM capacitor or the like) has a trench segment landing on a capacitor-bottom via. The capacitor-bottom via extends from the trench segment to a capacitor-bottom wire that underlies the capacitor to electrically couple the capacitor to the capacitor-bottom wire. The trench segment is one of a plurality of trench segments of the capacitor, and an additional trench segment of the plurality of trench segments is spaced from the capacitor-bottom via and a wire level at which the capacitor-bottom wire is located. This frees a portion of the wire level directly under the additional trench segment for signal routing.

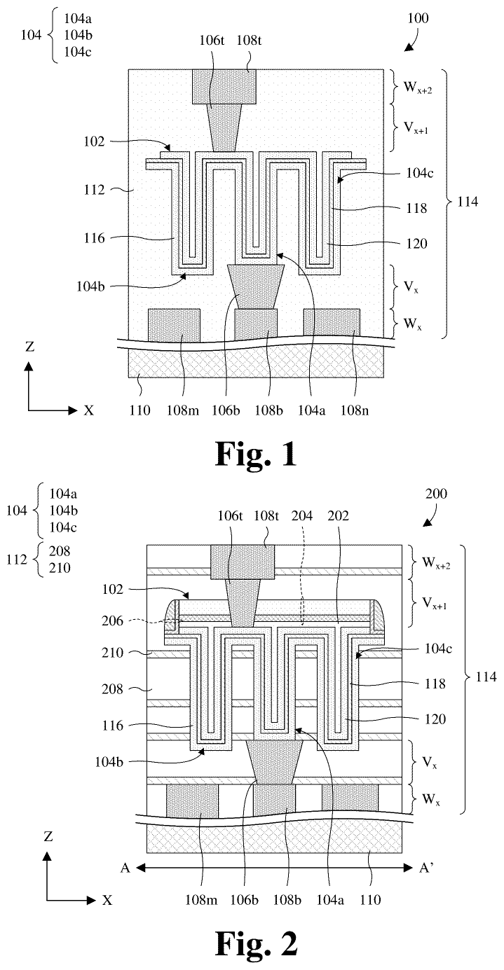

With reference to FIG. 1, a cross-sectional view 100 of some embodiments of an IC comprising a capacitor 102 with a first trench segment 104a landing on a capacitor-bottom via 106b is provided. The first trench segment 104a is one of a plurality of trench segments 104 of the capacitor 102 and is the only trench segment amongst the plurality of trench segments 104 that lands on a conductive structure (e.g., the capacitor-bottom via 106b). The remainder of the plurality of trench segments 104 land on dielectric material.

The capacitor-bottom via 106b extends downward from the first trench segment 104a to a capacitor-bottom wire 108b, which underlies and is spaced from the capacitor 102 in wire level Wₓ. As a result, the capacitor-bottom via 106b electrically couples the capacitor-bottom wire 108b to the capacitor 102 at the first trench segment 104a. Further, the capacitor-bottom via 106b spaces the plurality of trench segments 104 from wire level Wₓ, such that the plurality of trench segments 104 do not extend to any wire within wire level Wₓ.

Because the plurality of trench segments 104 are spaced from wire level Wₓ and do not land on the capacitor-bottom wire 108b, the capacitor-bottom wire 108b may be smaller than it would otherwise be. For example, the capacitor-bottom wire 108b may have a width closer to a width of the first trench segment 104a or a width of the capacitor-bottom via 106b than to a combined width of the plurality of trench segments 104. Note that the widths are in an X dimension extending horizontally in FIG. 1.

The reduced size of the capacitor-bottom wire 108b frees area within wire level Wₓ for signal routing via other wires, such as wire 108m or wire 108 n, in wire level Wₓ. The freed area may reduce the complexity of signal routing through and/or within wire level Wₓ and may hence reduce costs. Additionally, because minimum wire and via sizes and minimum wire and via spacings generally do not change when scaling down ICs, signal routing is expected to become more complicated over time with the continued scaling down of ICs. The area freed within wire level Wₓ helps mitigate this challenge as the IC is scaled down.

With continued reference to FIG. 1, the capacitor 102 overlies a substrate 110 in a dielectric structure 112. The substrate 110 may, for example, be or comprise a silicon substrate, a silicon-on-insulator (SOI) substrate, or some other suitable type of semiconductor substrate. Further, the capacitor 102 is surrounded by and electrically coupled to an interconnect structure 114 that is also in the dielectric structure 112. The capacitor 102 comprises a bottom electrode 116, a capacitor dielectric layer 118 overlying the bottom electrode 116, and a top electrode 120 overlying the capacitor dielectric layer 118. The capacitor 102 may, for example, be a 3D MIM capacitor or some other suitable type of capacitor.

The bottom electrode 116, the capacitor dielectric layer 118, and the top electrode 120 form and continuously connect the plurality of trench segments 104, which protrude towards the substrate 110 from a bottom of the capacitor 102. The bottom electrode 116 extends continuously from the capacitor-bottom via 106b at the first trench segment 104a to a remainder of the of the plurality of trench segments 104. As a result, portions of the bottom electrode 116 at the remainder of the plurality of trench segments 104 electrically couple indirectly to the capacitor-bottom via 106b through the first trench segment 104a. In some embodiments, the only conductive paths electrically coupling the remainder of the plurality of trench segments 104 to the capacitor-bottom via 106b extend through the first trench segment 104a.

The remainder of the plurality of trench segments 104 comprise a second trench segment 104b and a third trench segment 104c between which the first trench segment 104a is laterally arranged. Whereas the first trench segment 104a is at a width-wise center of the capacitor 102, the second and third trench segments 104b, 104c are at a periphery of the capacitor 102. The second and third trench segments 104b, 104c respectively overlie and are spaced from wire 108m and wire 108 n, which are in wire level Wₓ and which are therefore level with the capacitor-bottom wire 108b. Wire 108m and wire 108n are electrically isolated from the capacitor-bottom wire 108b and, in some embodiments, are electrically isolated from each other. Therefore, wire 108m and wire 108n may be used for routing signals unrelated to use and/or control of the capacitor 102 through and/or within wire level Wₓ.

The second and third trench segments 104b, 104c have individual heights that are greater than a height of the first trench segment 104a. Note that the heights are in a Z dimension extending vertically in FIG. 1. As a result of the height differential, the second and third trench segments 104b, 104c have individual bottom surfaces recessed relative to a bottom surface of the first trench segment 104a and recessed relative to a top surface of the capacitor-bottom via 106b. The height differential may, for example, result from different material hardnesses during etching to form trenches with which the plurality of trench segments 104 are formed. For example, material of the capacitor-bottom via 106b may be harder than material of the dielectric structure 112, whereby the etching may be slower at the material of the capacitor-bottom via 106b than at the material of the dielectric structure 112.

In some embodiments, the plurality of trench segments 104 have individual widths that are the same as each other. Note that the widths are in the X dimension. In other embodiments, the plurality of trench segments 104 have different widths. For example, the second and third trench segments 104b, 104c may have individual widths that are the same as each other and that are more or less than a width of the first trench segment 104a. In some embodiments, a bottom surface of the first trench segment 104a has a width that is less than a width of a top surface of the capacitor-bottom via 106b. In other embodiments, the width of the bottom surface of the first trench segment 104a is the same as or greater than the width of the top surface of the capacitor-bottom via 106b. In some embodiments, the first trench segment 104a has a bottom surface entirely or mostly contacting conductive material of the interconnect structure 114, whereas each other trench segment of the plurality of trench segments 104 has a bottom surface entirely contacting dielectric material of the dielectric structure 112.

In some embodiments, the bottom electrode 116 is or comprises titanium nitride, titanium, tungsten, platinum, some other suitable metal or metal nitride, some other suitable conductive material, or any combination of the foregoing. In some embodiments, the top electrode 120 is or comprises a same material as the bottom electrode 116 and/or is or comprises titanium nitride, titanium, tungsten, platinum, some other suitable metal or metal nitride, some other suitable conductive material, or any combination of the foregoing. In some embodiments, the capacitor dielectric layer 118 is or comprises silicon oxide, a metal oxide, some other suitable dielectric, or any combination of the foregoing. Further, in some embodiments, the capacitor dielectric layer 118 is or comprises a high k dielectric material having a dielectric constant greater than 3.9, 9, or some other suitable value.

The interconnect structure 114 comprises a plurality of wires and a plurality of vias respectively grouped into a plurality of wire levels and a plurality of vias that are stacked away from the substrate 110. The plurality of wires and the plurality of vias may, for example, also be known as conductive features or the like. The plurality of wire levels include wire level Wₓ and wire level Wₓ₊₂, whereas the plurality of via levels include via level Vₓ and via level Vₓ₊₁. Within the labels for the wire and via levels, x corresponds an integer index representing level or elevation above the substrate 110 and increases away from the substrate 110.

Wire level Wₓ includes the capacitor-bottom wire 108b underlying the capacitor 102, as noted above, and via level Vₓ includes the capacitor-bottom via 106b extending from the capacitor-bottom wire 108b to the bottom electrode 116. Wire level Wₓ₊₂ includes a capacitor-top wire 108t overlying the capacitor 102, and via level Vₓ₊₁ includes a capacitor-top via 106t extending from the capacitor-top wire 108t to the top electrode 120.

In some embodiments, the plurality of wires and/or the plurality of vias are or comprise copper, aluminum copper, some other suitable metals and/or conductive materials, or any combination of the foregoing. Further, in some embodiments, the dielectric structure 112 is or comprises one or more low k dielectric materials, one or more etch stop materials, some other suitable dielectric materials, or any combination of the foregoing. The one or more low k dielectric materials have dielectric constants less than 3.9, 3, or some other suitable value and may, for example, include at least one of undoped silicate glass (USG), boron-doped silicate glass (BSG), fluorine-doped silicate glass (FSG), or the like. The one or more etch stop materials may, for example, include silicon nitride, silicon carbide, or the like.

While the capacitor 102 is illustrated with only three trench segments in FIG. 1, the capacitor 102 may include more or less trench segments in alternative embodiments. For example, the capacitor 102 may include two, four, eight, or some other suitable number of trench segments. Further, while wire level Wₓ is illustrated as including wire 108m and wire 108n, wire 108m may be omitted and/or wire 108n may be omitted in alternative embodiments.

With reference to FIG. 2, a cross-sectional view 200 of some embodiments of the IC of FIG. 1 is provided in which the capacitor 102 and the dielectric structure 112 have additional detail. The capacitor 102 further comprises a gap fill layer 202, a hard mask 204, and a sidewall spacer structure 206, whereas the dielectric structure 112 further comprises a plurality of intermetal dielectric (IMD) layers 208 and a plurality of etch stop layers 210.

The gap fill layer 202 fills gaps at the plurality of trench segments 104 and partially forms the plurality of trench segments 104 together with the bottom electrode 116, the capacitor dielectric layer 118, and the top electrode 120. Further, the gap fill layer 202 overlies the top electrode 120 outside the plurality of trench segments 104. The gap fill layer 202 may, for example, be or comprise a dielectric oxide, a low k dielectric (examples listed above), some other suitable dielectric, or any combination of the foregoing.

The hard mask 204 overlies the gap fill layer 202 with a same width as the gap fill layer 202 and the top electrode 120. As seen hereafter, the hard mask 204 serves as mask while etching to pattern the top electrode 120 and the gap fill layer 202. The hard mask 204 is formed by a stack of two layers (not individually labeled) that are stacked away from the substrate 110. In alternative embodiments, the hard mask 204 is formed by only one layer or by more than two layers. The hard mask 204 may, for example, be or comprise silicon oxide, silicon oxynitride, silicon nitride, silicon carbide, some other suitable dielectric material(s), or any combination of the foregoing. In some embodiments, a bottom one of the two layers forming the hard mask 204 is silicon oxide or silicon oxynitride, whereas a top one of the two layers is silicon nitride. Other suitable dielectrics are, however, amenable for these two layers.

The sidewall spacer structure 206 overlies the capacitor dielectric layer 118 on common sidewalls formed by the top electrode 120, the gap fill layer 202, and the hard mask 204. As seen hereafter, the sidewall spacer structure 206 and the hard mask 204 collectively serve as mask while etching to pattern the bottom electrode 116 and the capacitor dielectric layer 118. The sidewall spacer structure 206 has a pair of spacer segments respectively on opposite sides of the capacitor 102, which may, for example, be continuously connected outside the cross-sectional view 200 of FIG. 2. Further, the sidewall spacer structure 206 is formed by two layers (not individually labeled). In alternative embodiments, the sidewall spacer structure 206 is formed by only one layer or by more than two layers. The sidewall spacer structure 206 may, for example, be or comprise silicon oxide, silicon oxynitride, silicon nitride, silicon carbide, some other suitable dielectric material(s), or any combination of the foregoing.

In some embodiments, one of the two layers forming the sidewall spacer structure 206 wraps around a bottom corner of the other one of the two dielectric layers. The one of the two layers may, for example, be or comprise silicon oxide, whereas the other one of the two layers may, for example, be silicon nitride, or vice versa. Other suitable dielectrics are, however, amenable for these two layers in alternative embodiments.

The plurality of intermetal dielectric (IMD) layers 208 and the plurality of etch stop layers 210 form the dielectric structure 112 and are alternatingly stacked away from the substrate 110. Further, the plurality of etch stop layers 210 are respectively at tops of the plurality of wire levels (e.g., wire level Wₓ and wire level Wₓ₊₂) and tops of the plurality of via levels (e.g., via level Vₓ and via level Vₓ₊₁). Note that there may be a wire level between via level Vₓ and via level Vₓ₊₁ that is not visible within FIG. 2.

The plurality of IMD layers 208 may, for example, be or comprise one or more low k dielectric materials and/or one or more other suitable dielectric materials. The one or more low k dielectric materials may, for example, have dielectric constants less than 3.9, 3, or some other suitable value and/or may, for example, include at least one of USG, BSG, FSG, or the like. The plurality of etch stop layers 210 may, for example, be or comprise silicon nitride, silicon oxynitride, silicon carbide, some other suitable dielectrics, or any combination of the foregoing.

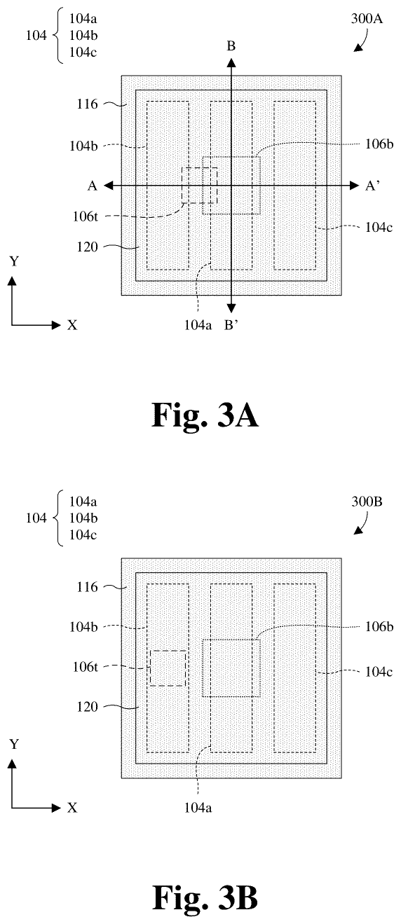

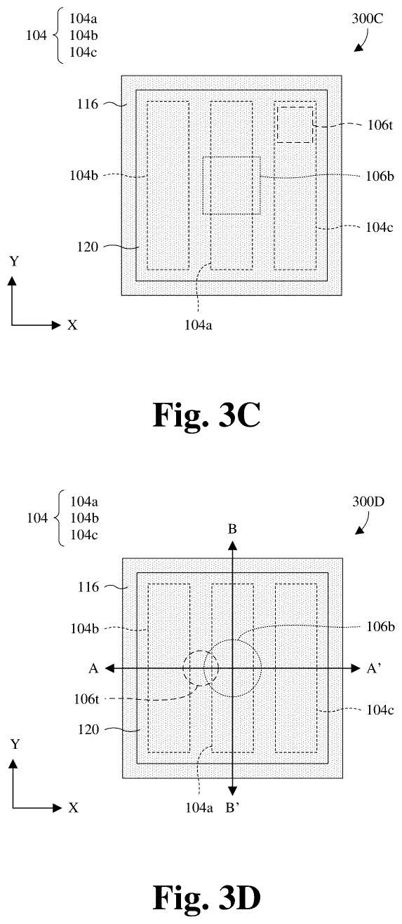

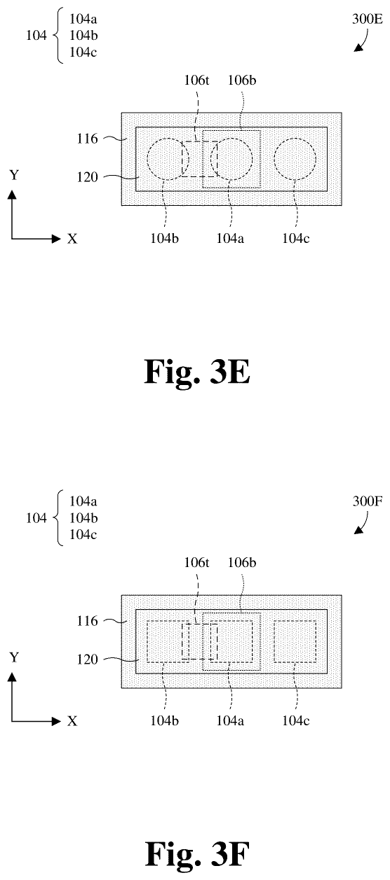

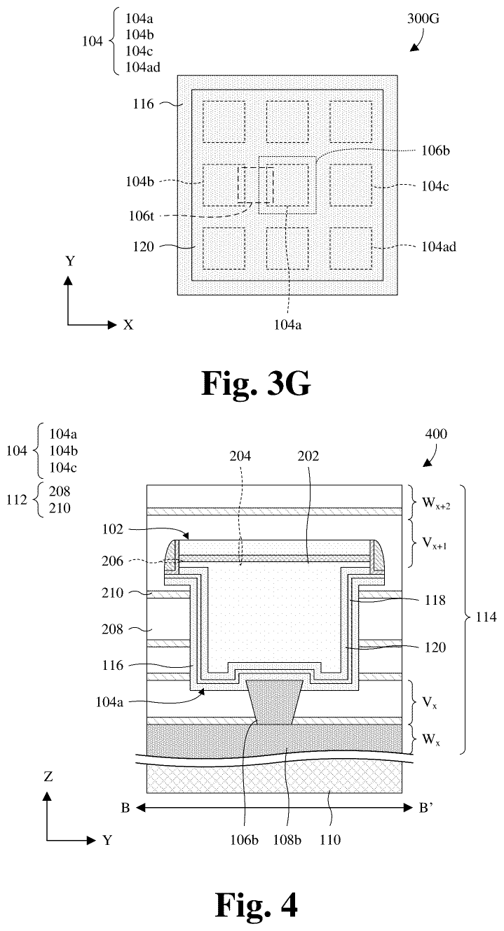

With reference to FIG. 3A, a top layout view 300A of some embodiments of the capacitor of FIG. 2 is provided. The cross-sectional view 200 of FIG. 2 may, for example, be taken along line A-A in FIG. 3A or along some other suitable line. Further, for clarity of illustration, certain structure (e.g., the hard mask 204, the sidewall spacer structure 206, etc.) is omitted and certain other structure (e.g., the plurality of trench segments 104, the capacitor-bottom via 106b, and the capacitor-top via 106t) is shown in phantom.

The plurality of trench segments 104 are elongated in parallel in a Y dimension, such that the plurality of trench segments 104 have individual greatest dimensions (e.g., lengths) in the Y dimension. Further, the plurality of trench segments 104 are evenly spaced from each other in the X dimension, which is orthogonal to the Y dimension. In alternative embodiments, spacing between the plurality of trench segments 104 may be non-uniform and/or vary.

The capacitor-bottom via 106b overlaps with the first trench segment 104a and is at a center of the first trench segment 104a in the Y dimension. In alternative embodiments, the capacitor-bottom via 106b is at an end of the first trench segment 104a in the Y dimension or at some other suitable location on the first trench segment 104 a. The capacitor-top via 106t is laterally between the first and second trench segments 104a, 104b in the X dimension and overlaps with the capacitor-bottom via 106b. Hence, the capacitor-top via 106t is at a center of the capacitor 102 in the Y dimension. In alternative embodiments, the capacitor-top via 106t is at a corner of the capacitor 102 or at some other suitable location on the capacitor 102.

With reference to FIGS. 3B and 3C, top layout views 300B, 300C of some alternative embodiments of the capacitor of FIG. 3A are provided in which the capacitor-top via 106t and the capacitor-bottom via 106b are non-overlapping.

In FIG. 3B, the capacitor-top via 106t is laterally offset from the capacitor-bottom via 106b in the X dimension, such that the capacitor-top via 106t and the capacitor-bottom via 106b are non-overlapping. Further, the capacitor-top via 106t and the capacitor-bottom via 106b are on a common axis extending in the X dimension.

In FIG. 3C, the capacitor-top via 106t is laterally offset from the capacitor-bottom via 106b in both the X dimension and the Y dimension, such that the capacitor-top via 106t and the capacitor-bottom via 106b are non-overlapping. Further, the capacitor-top via 106t is shifted to a top-right corner of the capacitor.

While FIGS. 3A-3C illustrate certain relative positionings between the capacitor-top via 106t and the capacitor-bottom via 106b, these relative positionings may be varied in alternative embodiments. For example, a position of the capacitor-bottom via 106b may be varied so long as the capacitor-bottom via 106b remains overlapping with the first trench segment 106a. Additionally, a position of the capacitor-top via 106t may be varied so long as the capacitor-top via 106t remains overlapping with the top electrode 120.

With reference to FIG. 3D, a top layout view 300D of some alternative embodiments of the capacitor of FIG. 3A is provided in which the capacitor-top via 106t and the capacitor-bottom via 106b are circular. In alternative embodiments, the capacitor-top via 106t and the capacitor-bottom via 106b may have some other non-polygonal shape (e.g., elliptical, oval, etc.) or a polygonal shape (e.g., triangle, rectangle, hexagon, etc.). Further, in alternative embodiments, the capacitor-top via 106t and the capacitor-bottom via 106b may have some other suitable sizes. Further yet, in alternative embodiments, the capacitor-top via 106t and the capacitor-bottom via 106b may have different shapes. For example, the capacitor-top via 106t may be circular, whereas the capacitor-bottom via 106b may be polygonal, or vice versa.

With reference to FIGS. 3E and 3F, top layout views 300E, 300F of some alternative embodiments of the capacitor of FIG. 3A are provided in which the plurality of trench segments 104 have different shapes. In FIG. 3E, the plurality of trench segments 104 are circular. Therefore, in some embodiments, the plurality of trench segments 104 may be cylindrical or have some other suitable shape when viewed in perspective. In FIG. 3F, the plurality of trench segments 104 are square shaped. While FIGS. 3E and 3F illustrate certain shapes for the plurality of trench segments 104, other polygonal shapes (e.g., triangle, hexagon, etc.) or non-polygonal shapes (e.g., elliptical, oval, etc.) are amenable in alternative embodiments.

With reference to FIG. 3G, a top layout view 300G of some alternative embodiments of the capacitor of FIG. 3A is provided in which the plurality of trench segments 104 include additional trench segments 104ad and in which the plurality of trench segments 104 are in a plurality of rows and a plurality of columns. The plurality of rows extend in parallel in the X dimension, and the plurality of columns extend in parallel in the Y dimension. In alternative embodiments, there may be more or less rows and/or more or less columns.

The additional trench segments 104ad may be individually as the second and third trench segment 104b, 104c are described with FIGS. 1 and 2. Hence, when viewed in cross section, the additional trench segments 104ad land on dielectric material instead of conductive material of the interconnect structure 114 of FIGS. 1 and 2. Further, the plurality of trench segments 104 are square shaped. In alternative embodiments, the plurality of trench segments 104 may have some other suitable polygonal shape (e.g., triangle, hexagon, rectangle, etc.), a rod shape, or a non-polygonal shape (e.g., elliptical, oval, circle, etc.). Further, in alternative embodiments, the plurality of trench segments 104 may have some other suitable size.

With reference to FIG. 4, an additional cross-sectional view 400 of some embodiments of the IC of FIG. 2 and/or FIG. 3A is provided. The additional cross-sectional view 400 may, for example, be taken along line B-B′ or some other suitable line in FIG. 3A. Further, in contrast with the cross-sectional view 200 of the FIG. 2, which is taken in the X-Z plane, the additional cross-sectional view 400 is taken in the Y-Z plane.

The capacitor-bottom wire 108b and the first trench segment 104a are elongated in parallel in the Y dimension, and the capacitor-bottom via 106b extends from the capacitor-bottom wire 108b to the first trench segment 104a. Further, the capacitor-bottom via 106b is inset into a bottom of the first trench segment 104a. As such, the first trench segment 104a wraps around top corners of the capacitor-bottom via 106b from a top surface of the capacitor-bottom via 106b to sidewalls of the capacitor-bottom via 106b. Further, because the capacitor-bottom via 106b has slanted sidewalls, the top corners of the capacitor-bottom via 106b may, for example, overhang portions of the bottom electrode 116.

In alternative embodiments, the capacitor-bottom via 106b may not be inset into the bottom of the first trench segment 104a. As such, the first trench segment 104a may have a planar bottom profile or some other suitable bottom profile.

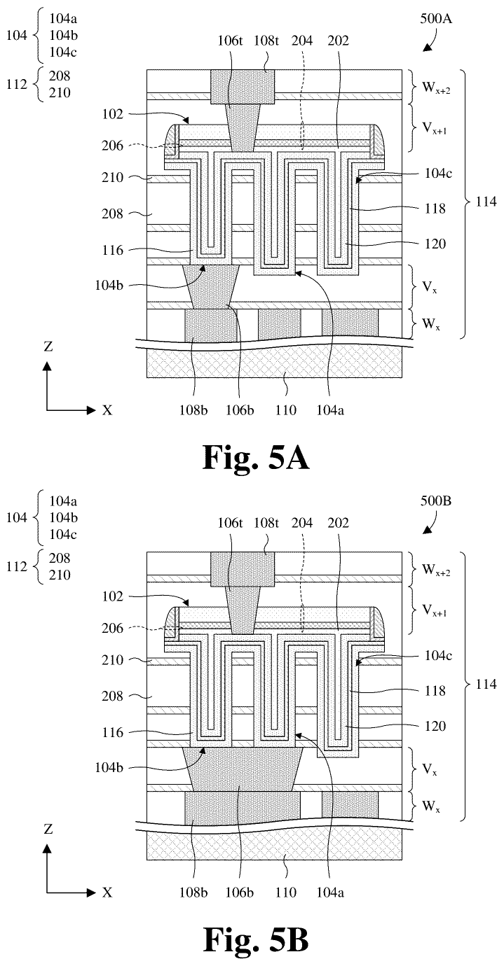

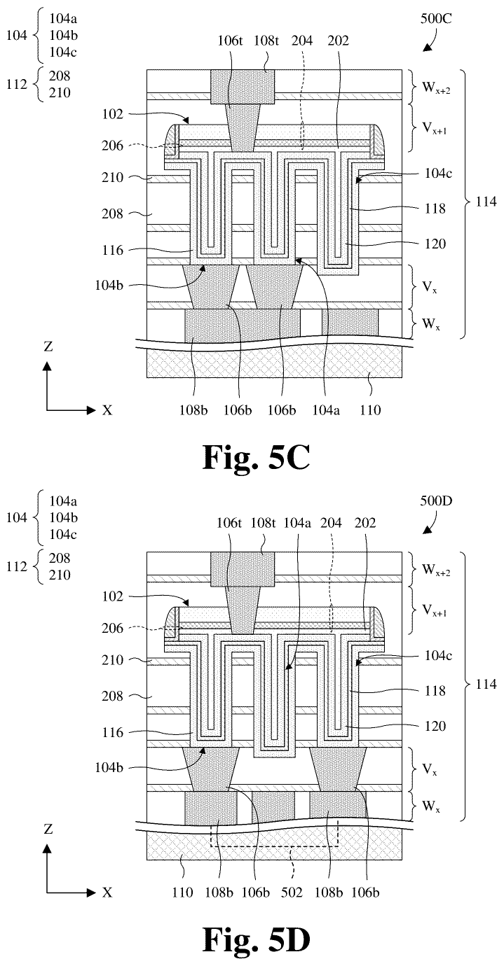

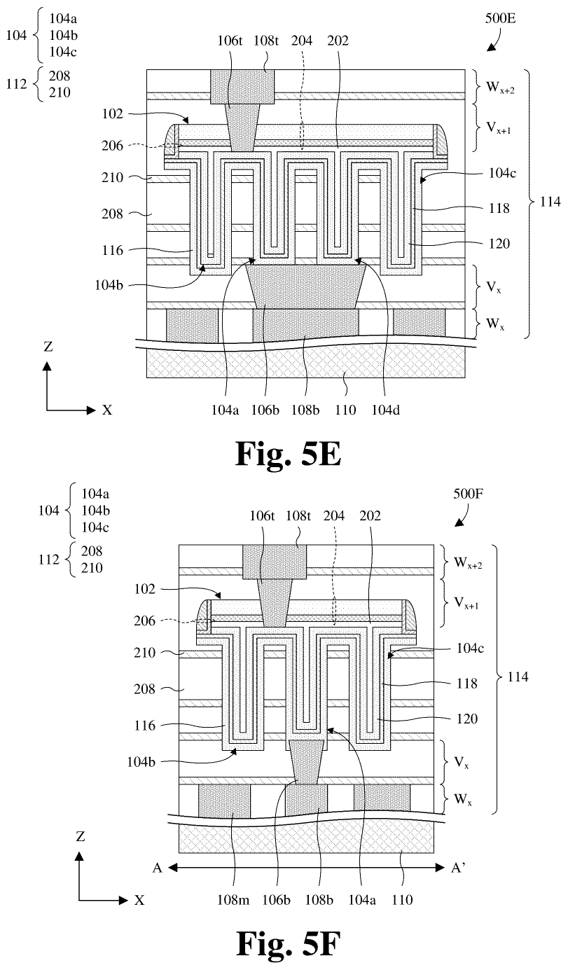

With reference to FIGS. 5A-5F, cross-sectional views 500A-500F of some alternative embodiments of the IC of FIG. 2 are provided in which the capacitor 102 and surrounding structure (e.g., the capacitor-bottom via 106b) are varied.

In FIG. 5A, the capacitor-bottom via 106b and the capacitor-bottom wire 108b underlie the second trench segment 104b rather than the first trench segment 104a. As such, the second trench segment 104b is the only trench segment amongst the plurality of trench segments 104 that lands on a conductive structure (e.g., the capacitor-bottom via 106b). The remainder of the plurality of trench segments 104 land on dielectric material.

In FIG. 5B, the capacitor-bottom via 106b is enlarged so the first and second trench segments 104a, 104b land on the capacitor-bottom via 106b. The remainder of the plurality of trench segments 104 land on dielectric material. This embodiment (and the embodiments of FIGS. 5C-5E, which are discussed hereafter) may, for example, increase contact area between the bottom electrode 116 and the interconnect structure 114 for a reduced contact resistance.

In FIG. 5C, the capacitor-bottom wire 108b is enlarged to accommodate a pair of capacitor-bottom vias 106b. The pair of capacitor-bottom vias 106b respectively underlie the first and second trench segments 104a, 104b and extend from the capacitor-bottom wire 108b respectively to the first and second trench segments 104a, 104b. Hence, the first and second trench segments 104a, 104b land respectively on the pair of capacitor-bottom vias 106b, whereas a remainder of the plurality of trench segments 104 land on dielectric material.

In FIG. 5D, a pair of capacitor-bottom wires 108b respectively underlie the second and third trench segments 104b, 104c and are electrically coupled to each other outside the cross-sectional view 500D by a conductive path 502 (schematically illustrated). In alternative embodiments, the pair of capacitor-bottom wires 108b correspond to portions of a common wire and are continuously connected outside the cross-sectional view 500D.

A pair of capacitor-bottom vias 106b extend respectively from the pair of capacitor-bottom wires 108b respectively to the second and third trench segments 104b, 104c. Hence, the second and third trench segments 104b, 104c land respectively on the pair of capacitor-bottom vias 106b, and a remainder of the plurality of trench segments 104 land on dielectric material.

In FIG. 5E, the capacitor 102 further comprises a fourth trench segment 104d between the first trench segment 104a and the third trench segment 104c. Further, the capacitor-bottom via 106b is enlarged so the first and fourth trench segments 104a, 104d land on the capacitor-bottom via 106b. The remainder of the plurality of trench segments 104 land on dielectric material. In alternative embodiments, the capacitor-bottom via 106b is replaced with a pair of capacitor-bottom vias extending from the first and fourth trench segments 104a, 104d to the capacitor-bottom wire 108b (similar to FIG. 5C).

In FIG. 5F, the first trench segment 104a has a width greater than a width of the capacitor-bottom via 106b. Note that the widths are in an X dimension extending horizontally in FIG. 5F. Further, the first trench segment 104a may have a bottom surface recessed relative to a top surface of the capacitor-bottom via 106b and level with a bottom surface of the second trench segment 104b. This may, for example, result from a faster etch rate at the dielectric structure 112 than at the capacitor-bottom via 106b during etching to form trenches within which the plurality of trench segments 104 are arranged.

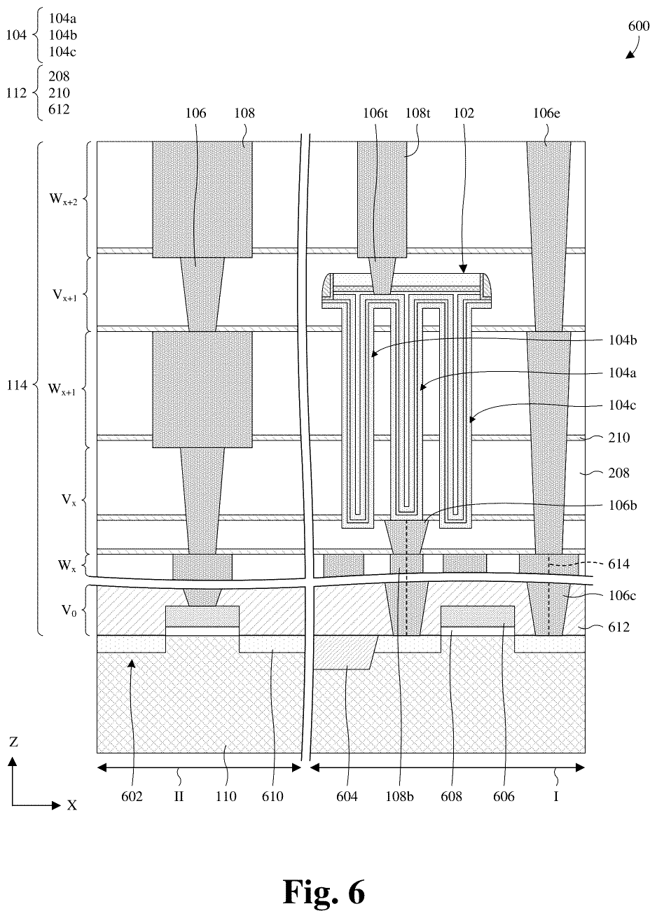

With reference to FIG. 6, a cross-sectional view 600 of some embodiments of the IC of FIG. 2 is provided in which the IC includes a first device region I at which the capacitor 102 is arranged and further includes a second device region II. In some embodiments, the first device region I corresponds to a pixel circuit, and the second device region II corresponds to a logic circuit. However, other suitable types of circuits are amenable for the first device region I and/or the second device region II in alternative embodiments.

A plurality of transistors 602 overlie the substrate 110, between the substrate 110 and the interconnect structure 114. Further, the plurality of transistors 602 are separated from each other by a trench isolation structure 604 extending into the substrate 110. The plurality of transistors 602 comprise individual gate electrodes 606, individual gate dielectric layers 608, and individual pairs of source/drain regions 610. The gate electrodes 606 are separated from the substrate 110 respectively by the gate dielectric layers 608 and are sandwiched between corresponding source/drain regions of the pairs of source/drain regions 610.

The interconnect structure 114 overlies and is electrically coupled to the plurality of transistors 602 and surrounds and is electrically coupled to the capacitor 102. The interconnect structure 114 comprises a plurality of wires 108 and a plurality of vias 106 respectively grouped into a plurality of wire levels and a plurality of vias that are alternatingly stacked away from the substrate 110. The plurality of wire levels include wire level Wₓ, wire level Wₓ₊₁, and wire level Wₓ₊₂, whereas the plurality of via levels include via level V₀, via level Vₓ, and via level Vₓ₊₁. x may, for example, be 1, 2, 3 or some other suitable value.

Depending on the value of x, there may be zero or more additional wire levels and zero or more additional via levels alternatingly and vertically stacked between via level V₀ and wire level Wₓ. For example, where x is 1, there may be no additional wire and via levels, whereby wire level Wₓ may overlie and directly contact via level V₀. As another example, where x is 2, there be an additional wire level and an additional via level vertically stacked between via level V₀ and wire level Wₓ. The additional wire level may overlie and directly contact via level V₀, the additional via level may overlie and directly contact the additional wire level, and wire level Wₓ may overlie and directly contact the additional via level.

The plurality of vias 106 comprise a plurality of contact vias 106c, a plurality of extended vias 106e, the capacitor-bottom via 106b, and the capacitor-top via 106t. The capacitor-top via 106t and the capacitor-bottom via 106b are as described above and extend respectively from the top of the capacitor 102 and the bottom of the capacitor 102. The plurality of extended vias 106e are each in both a via level and a wire level. In contrast, other vias of the plurality of vias 106 are generally in a via level, but not a wire level.

The plurality of contact vias 106c extend from semiconductor devices (e.g., being or otherwise including the plurality of transistors 602) in the substrate 110. Further, the plurality of contact vias 106c form via level V₀, whereby via level V₀ may also be referred to as a contact via level. Whereas a remainder of the plurality of vias 106 are in the plurality of IMD layers 208 and the plurality of etch stop layers 210, the plurality of contact vias 106c are in an interlayer dielectric (ILD) layer 612. The ILD layer 612 partially forms the dielectric structure 112 and is or comprises a low k dielectric and/or some other suitable dielectric.

In some embodiments, the interconnect structure 114 forms a plurality of conductive paths 614 (schematically shown by dashed lines) electrically coupling the capacitor 102 and the plurality of extended vias 106e to a common one of the plurality of transistors 602. For example, the capacitor 102 may be electrically coupled to a first source/drain region of the common transistor, whereas the plurality of extended vias 106e may be electrically coupled to a second source/drain region of the common transistor.

While the IC of FIG. 6 is illustrated with embodiments of the capacitor 102 and surrounding structure as in FIG. 2, alternative embodiments of the IC of FIG. 6 may employ embodiments of the capacitor 102 and surrounding structure as in any one or combination of FIGS. 5A-5F. Further, while the top layout view 300A of FIG. 3A is described with regard to the capacitor 102 of FIG. 2, the top layout view 300A is applicable to the capacitor 102 in any one or combination of FIGS. 5A-5F and 6. For example, the cross section of the capacitor 102 in FIG. 6 may be taken along line A-A′ in FIG. 3A. Further yet, while the additional cross-sectional view 400 of FIG. 4 is described with regard to the capacitor 102 of FIG. 2 and/or FIG. 3A, the additional cross-sectional view 400 is applicable to the capacitor 102 in any one or combination of FIGS. 5A-5F and 6. For example, the additional cross-sectional view 400 may provide a view of the capacitor 102 of FIG. 6 in a cross-sectional plane orthogonal to that of FIG. 6.

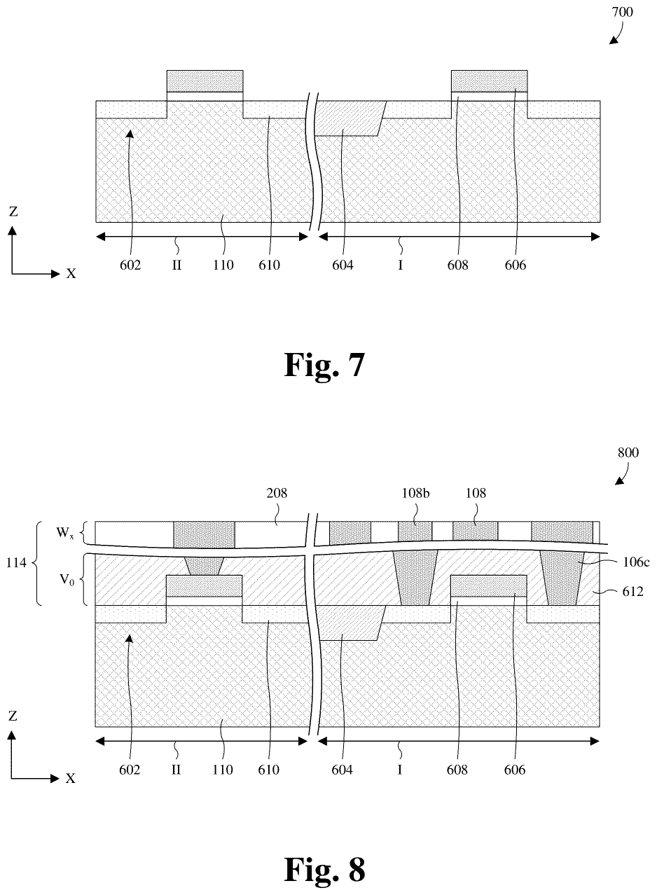

With reference to FIGS. 7-21, a series of cross-sectional views 700-2100 of some embodiments of an IC comprising a capacitor 102 with a first trench segment 104a landing on a capacitor-bottom via 106b is provided. The capacitor 102 and surrounding structure formed by the method may, for example, be as in FIG. 6 of the present application, and/or the cross-sectional views 700-2100 may, for example, correspond to line A-A′ in FIG. 3A.

As illustrated by the cross-sectional view 700 of FIG. 7, a plurality of transistors 602 separated by a trench isolation structure 604 are formed overlying a substrate 110, respectively at a first device region I and a second device region II of the IC being formed. The plurality of transistors 602 comprise individual gate electrodes 606, individual gate dielectric layers 608, and individual pairs of source/drain regions 610. In alternative embodiments, more transistors and/or different semiconductor devices may be formed overlying the substrate 110.

As illustrated by the cross-sectional view 800 of FIG. 8, an interconnect structure 114 is partially formed overlying and electrically coupled to the plurality of transistors 602. The interconnect structure 114 comprises via level V₀ and wire level Wₓ. x is an integer index representing wire and via level above a substrate and may, for example, be 1, 2, 3, or more. Depending on the value of x, there may be zero or more via levels and zero or more wire levels alternatingly stacked between via level V₀ and wire level Wₓ.

Via level V₀ comprises a plurality of contact vias 106c in an ILD layer 612, which overlies the plurality of transistors 602 and the substrate 110. Wire level Wₓ overlies via level V₀ at a top of the interconnect structure 114 and is in an IMD layer 208. Further, wire level Wₓ comprises a plurality of wires 108, including a capacitor-bottom wire 108b. In some embodiments, the ILD layer 612 and the IMD layer 208 (and any intervening dielectric layers) may collectively be referred to as a zeroth dielectric structure.

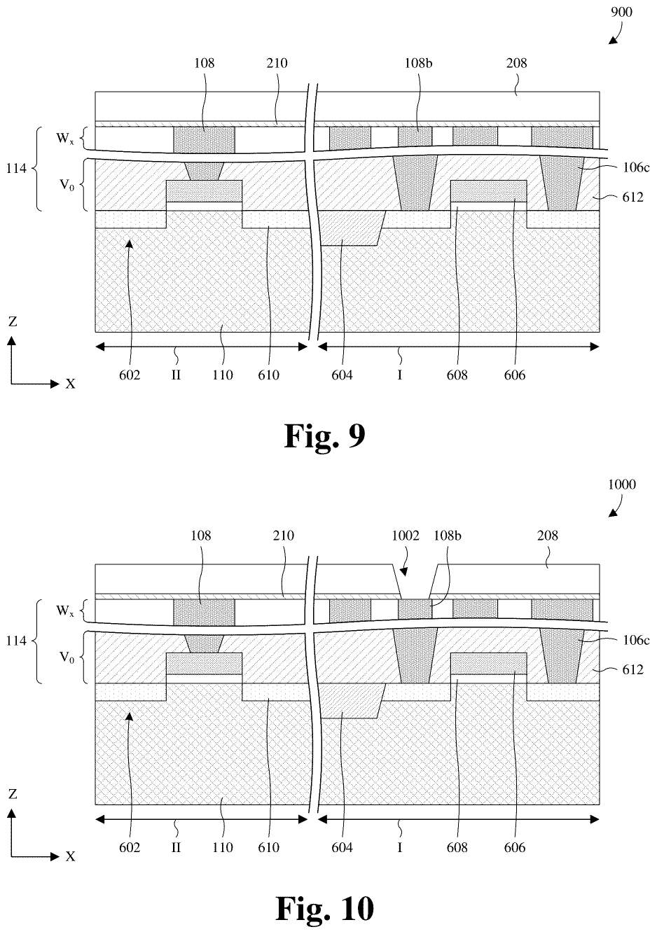

As illustrated by the cross-sectional view 900 of FIG. 9, an etch stop layer 210 and an additional IMD layer 208 are deposited over the interconnect structure 114. The etch stop layer 210 is deposited overlying the interconnect structure 114 and then the additional IMD layer 208 is deposited overlying the etch stop layer 210. In some embodiments, the etch stop layer 210 and the additional IMD layer 208 may collectively be referred to as a first dielectric structure.

As illustrated by the cross-sectional view 1000 of FIG. 10, the etch stop layer 210 and the additional IMD layer 208 (e.g., the first dielectric structure) are patterned to form a via opening 1002 overlying and exposing the capacitor-bottom wire 108b. In some embodiments, the via opening 1002 has a top layout matching a top layout of the capacitor-bottom via 106b in any of FIGS. 3A-3G. The patterning may, for example, be performed by a photolithography/etching process or by some other suitable patterning process. The photolithography/etching process may, for example, be or comprise forming a photoresist mask overlying the additional IMD layer 208, performing an etch into the additional IMD layer 208 and the etch stop layer 210 with the photoresist mask in place, and removing the photoresist mask. In some embodiments, the etch stop layer 210 serves as an etch stop while etching to minimize damage to the capacitor-bottom wire 108b.

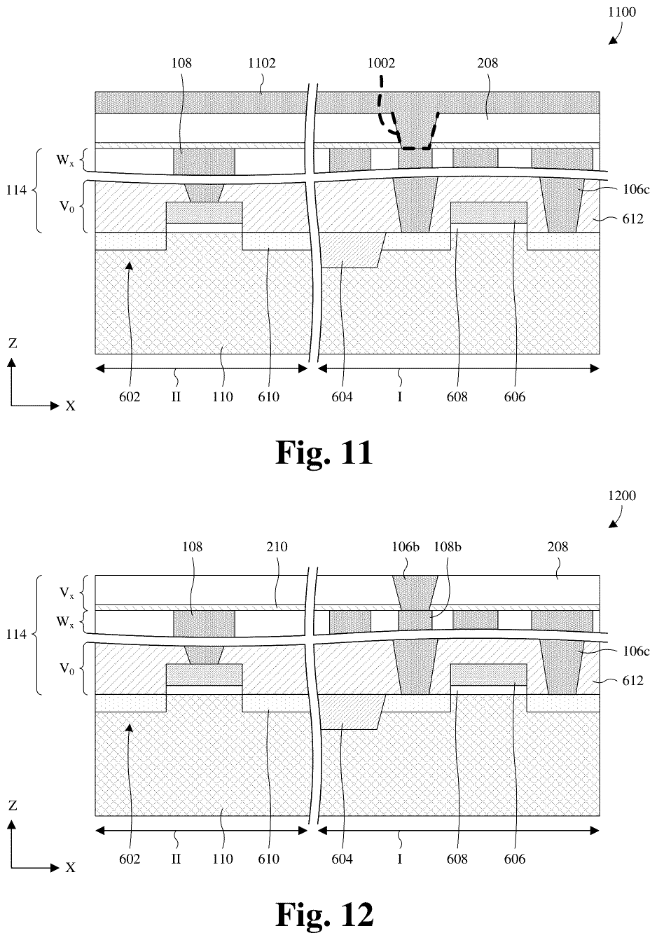

As illustrated by the cross-sectional view 1100 of FIG. 11, a conductive layer 1102 is deposited overlying the additional IMD layer 208 and filling the via opening 1002. The conductive layer 1102 may, for example, be or comprise copper, aluminum copper, some other suitable conductive material, or any combination of the foregoing.

As illustrated by the cross-sectional view 1200 of FIG. 12, a planarization is performed into the conductive layer 1102 until the additional IMD layer 208 is reached to clear the conductive layer 1102 from atop the additional IMD layer 208 and form a capacitor-bottom via 106b in the via opening 1002 (see, e.g., FIG. 10). This, in turn, extends the interconnect structure 114 with via level Vₓ. The planarization may, for example, be performed by a chemical mechanical polish (CMP) and/or some other suitable planarization process.

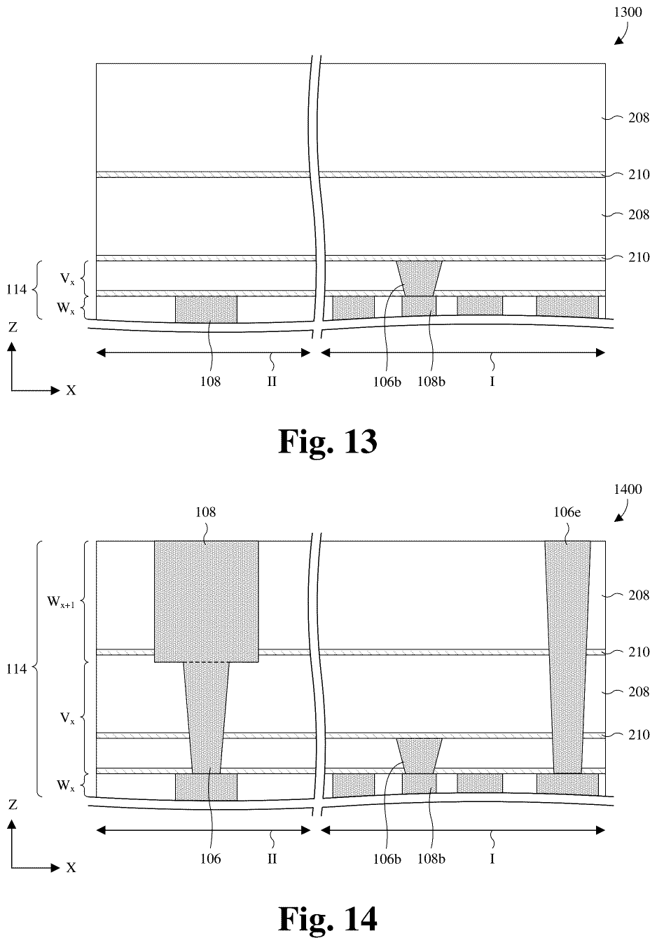

As illustrated by the cross-sectional view 1300 of FIG. 13, a pair of additional etch stop layers 210 and a pair of additional IMD layers 208 are deposited alternatingly and vertically stacked over via level Vₓ. Note that within FIGS. 13 to 21, a lower portion of the IC being formed (seen in FIGS. 7-12) is omitted for drawing compactness. One of the pair of additional etch stop layers 210 is deposited over via level Vₓ, followed by deposition of one of the pair of additional IMD layers 208, followed by deposition of another one of the pair of additional etch stop layers 210, and followed by deposition of another one of the pair of additional IMD layers 208. In some embodiments, the pair of additional etch stop layers 210 and the pair of additional IMD layers 208 may collectively be referred to as a second dielectric structure.

As illustrated by the cross-sectional view 1400 of FIG. 14, a plurality of additional vias 106, including an extended via 106e, and an additional wire 108 are formed in the pair of additional etch stop layers 210 and the pair of additional IMD layers 208 (e.g., the second dielectric structure). The plurality of additional vias 106 are level with the capacitor-bottom via 106b and are hence regarded as being part of and as extending via level Vₓ. The additional wire 108 overlies a corresponding one of the additional vias 106 at the second device region II. Further, the additional wire 108 forms wire level Wₓ₊₁ to extend the interconnect structure 114.

A process for forming the plurality of additional vias 106 and the additional wire 108 may comprise patterning the pair of additional etch stop layers 210 and the pair of additional IMD layers 208 to form openings corresponding to the plurality of additional vias 106 and the additional wire 108. Further, the process may comprise filling the openings with a conductive layer and subsequently performing a planarization into the conductive layer to clear the conductive layer from atop the pair of additional IMD layers 208. In other embodiments, the forming may be performed by some other suitable process.

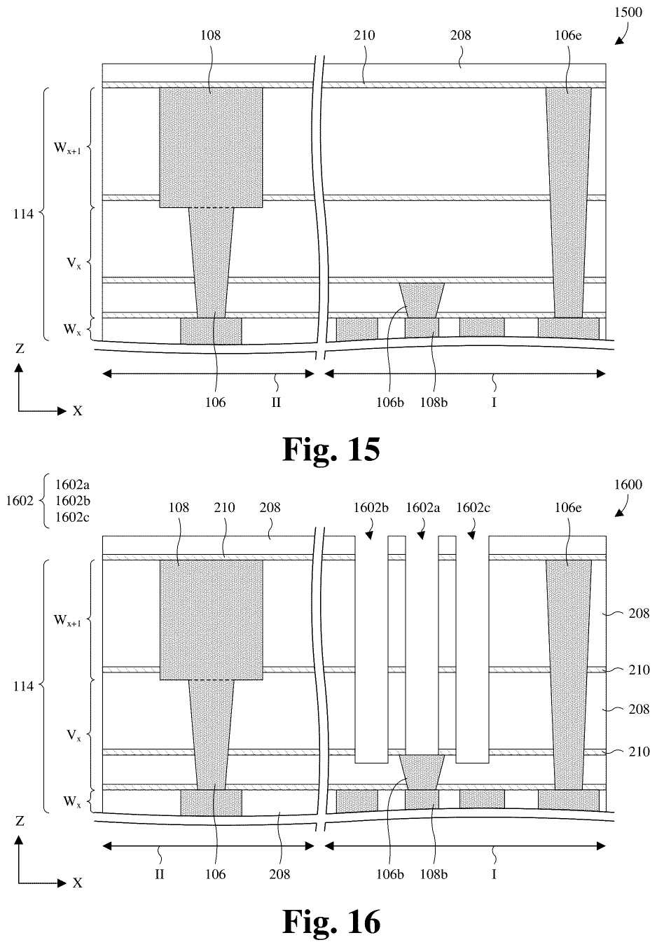

As illustrated by the cross-sectional view 1500 of FIG. 15, an additional etch stop layer 210 and an additional IMD layer 208 are deposited over wire level Wₓ₊₁. The additional etch stop layer 210 is deposited overlying wire level Wₓ₊₁ and then the additional IMD layer 208 is deposited. In some embodiments, the additional etch stop layer 210 and the additional IMD layer 208 may collectively be referred to as a third dielectric structure.

As illustrated by the cross-sectional view 1600 of FIG. 16, etch stop layers 210 and IMD layers 208 are patterned at the first device region I to form a plurality of trenches 1602. A first trench 1602a overlies and exposes the capacitor-bottom via 106b, whereas a remainder of the plurality of trenches 1602 (e.g., including a second trench 1602b and a third trench 1602c) are respectively on opposite sides of the capacitor-bottom via 106b and are laterally offset from the capacitor-bottom via 106b. Whereas the first trench 1602a lands on the capacitor-bottom via 106b, the remainder of the plurality of trenches 1602 land on only dielectric material (e.g., material of an IMD layer 208).

The patterning may, for example, be performed by a photolithography/etching process or by some other suitable patterning process. The patterning may, for example, be or comprise forming a mask overlying a topmost one of the IMD layers 208, performing an etch into the various dielectric layers underlying the mask, and removing the mask. The mask may, for example, be a photoresist mask, a hard mask patterned using a photoresist mask, or the like. In some embodiments, the etch stop layer 210 at the capacitor-bottom via 106b serves as an etch stop while etching to minimize damage to the capacitor-bottom via 106b.

In some embodiments, the plurality of trenches 1602 have a top layout matching a top layout of the plurality of trench segments 104 in FIG. 3A. For example, the plurality of trenches 1602 may be elongated (e.g., have greatest dimensions) extending in parallel with each other into and out of the cross-sectional view 1600 of FIG. 16. In alternative embodiments, the plurality of trenches 1602 have a top layout matching a top layout of the plurality of trench segments 104 in in any of FIGS. 3B-3G.

In some embodiments, a height of the first trench 1602a is greater than individual heights of the remainder of the plurality of trenches 1602. Note that height corresponds to a Z dimension extending vertically in FIG. 16. The height differential between the first trench 1602a and the remainder of the plurality of trenches 1602 may, for example, be due to different material hardnesses during etching to form the plurality of trenches 1602. For example, the capacitor-bottom via 106b may be harder than neighboring dielectric material, whereby etching at the first trench 1602a may be minimal once the capacitor-bottom via 106b is reached. In contrast, the remainder of the plurality of trenches 1602 do not land on the capacitor-bottom via 106b, whereby etching at the remainder of the plurality of trenches 1602 is at a greater rate than at the first trench 1602a once the etching reaches a depth of the capacitor-bottom via 106b.

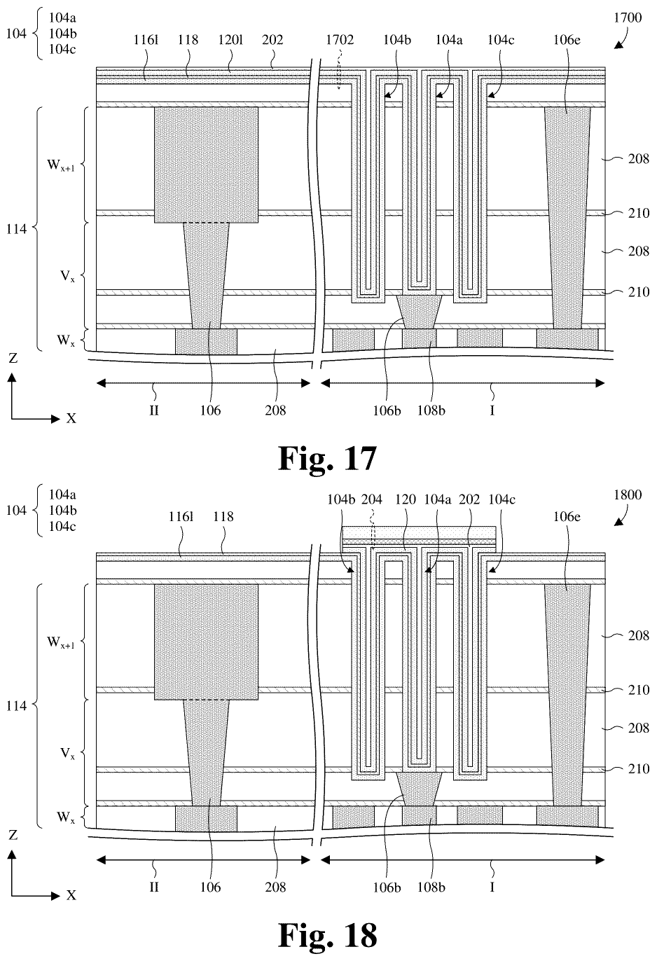

As illustrated by the cross-sectional view 1700 of FIG. 17, a multilayer capacitor film 1702 is deposited overlying a topmost one of the IMD layers 208 and filling the plurality of trenches 1602 (see, e.g., FIG. 16). The multilayer capacitor film 1702 comprises a bottom electrode layer 116l, a capacitor dielectric layer 118 overlying the bottom electrode layer 116l, a top electrode layer 120l overlying the capacitor dielectric layer 118, and a gap fill layer 202 overlying the top electrode layer 120l. In some embodiments, a planarization may, for example, be performed to flatten a top surface of the gap fill layer 202 after deposition of the gap fill layer 202. In alternative embodiments, the gap fill layer 202 is self-leveling.

Each layer of the multilayer capacitor film 1702 overlies a topmost one of the IMD layers 208 outside the plurality of trenches 1602 and partially fills each trench of the plurality of trenches 1602. Further, each layer of the multilayer capacitor film 1702 continuously connects each of the plurality of trenches 1602 to each other one of the plurality of trenches 1602. Portions of the multilayer capacitor film 1702 in the plurality of trenches 1602 respectively form a plurality of trench segments 104 for a capacitor being formed.

The plurality of trench segments 104 include a first trench segment 104a overlying and electrically coupled to the capacitor-bottom via 106b and further include a second trench segment 104b and a third trench segment 104c respectively on opposite sides of the first trench segment 104a and spaced from the capacitor-bottom via 106b. Because the second trench segment 104b and a third trench segment 104c are spaced from the capacitor-bottom via 106b and land on only dielectric material, these trench segments electrically couple to the capacitor-bottom via 106b only through the first trench segment 104a.

As illustrated by the cross-sectional view 1800 of FIG. 18, a hard mask 204 is formed overlying the gap fill layer 202 and then an etch is performed into the gap fill layer 202 and the top electrode layer 120l (see, e.g., FIG. 17) with the hard mask 204 in place to pattern the gap fill layer 202 and the top electrode layer 120l. The etch forms a top electrode 120 from the top electrode layer 120l and localizes a portion of the gap fill layer 202 to the top electrode 120.

The hard mask 204 is formed from two layers (not individually labeled) that are stacked vertically (e.g., in a Z dimension). In alternative embodiments, the hard mask 204 is formed from only one layer or is formed from more than two layers. A process for forming the hard mask 204 may, for example, comprise depositing one or more hard mask layers and then patterning the one or more hard mask layers by a photolithography/etching process. Other suitable processes are, however, amenable for forming the hard mask 204.

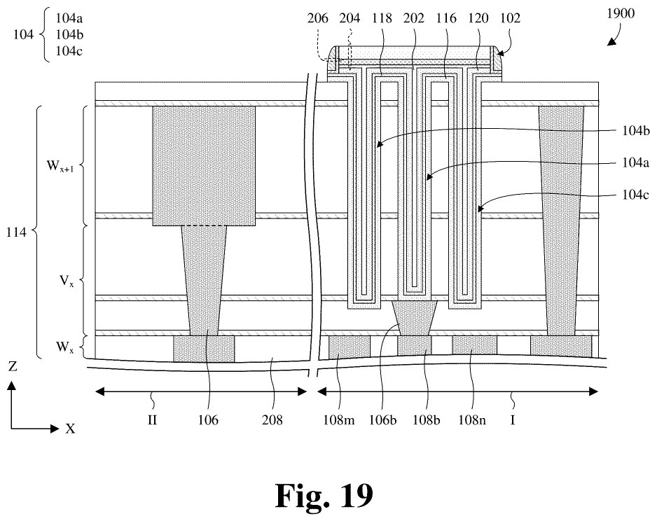

As illustrated by the cross-sectional view 1900 of FIG. 19, a sidewall spacer structure 206 is formed overlying the capacitor dielectric layer 118 on common sidewalls formed collectively by the hard mask 204, the gap fill layer 202, and the top electrode 120. Further, an etch is thereafter performed into the capacitor dielectric layer 118 and the bottom electrode layer 116l (see, e.g., FIG. 18) with the hard mask 204 and the sidewall spacer structure 206 in place to pattern the capacitor dielectric layer 118 and the bottom electrode layer 116l. The etch forms a bottom electrode 116 from the bottom electrode layer 116l and localizes a portion of the capacitor dielectric layer 118 to the bottom electrode 116.

The sidewall spacer structure 206 is formed by two layers (not individually labeled). In alternative embodiments, the sidewall spacer structure 206 is formed by only one layer or by more than two layers. A process for forming the sidewall spacer structure 206 may, for example, comprise depositing one or more sidewall spacer layers overlying the capacitor dielectric layer 118 and the hard mask 204 and further on the common sidewalls formed collectively by the hard mask 204, the gap fill layer 202, and the top electrode 120. Thereafter, the process may, for example, comprise etching back the one or more sidewall spacer layers. Other suitable processes are, however, amenable for forming the sidewall spacer structure 206.

Completion of the acts described with regard to FIG. 19 yields a capacitor 102. The capacitor 102 comprises the plurality of trench segments 104 and may, for example, be a 3D MIM capacitor or some other suitable type of capacitor. Amongst the plurality of trench segments 104, the first trench segment 104a is the only trench segment that lands on a conductive structure (e.g., the capacitor-bottom via 106b). The remainder of the plurality of trench segments 104 land on dielectric material.

Because the plurality of trench segments 104 are spaced from wire level Wₓ and do not land on the capacitor-bottom wire 108b, the capacitor-bottom wire 108b may be smaller than it would otherwise be. For example, the capacitor-bottom wire 108b may have a width closer to a width of the first trench segment 104a or a width of the capacitor-bottom via 106b than to a combined width of the plurality of trench segments 104. Note that width corresponds to an X dimension extending horizontally in FIG. 19.

The reduced size of the capacitor-bottom wire 108b frees area within wire level Wₓ for signal routing via other wires in wire level Wₓ. The freed area may reduce the complexity of signal routing through and/or within wire level Wₓ and may hence reduce costs. Additionally, because minimum wire and via sizes and minimum wire and via spacings generally do not change when scaling down ICs, signal routing is expected to become more complicated over time with the continued scaling down of ICs. The area freed within wire level Wₓ helps mitigate this challenge as the IC being formed is scaled down.

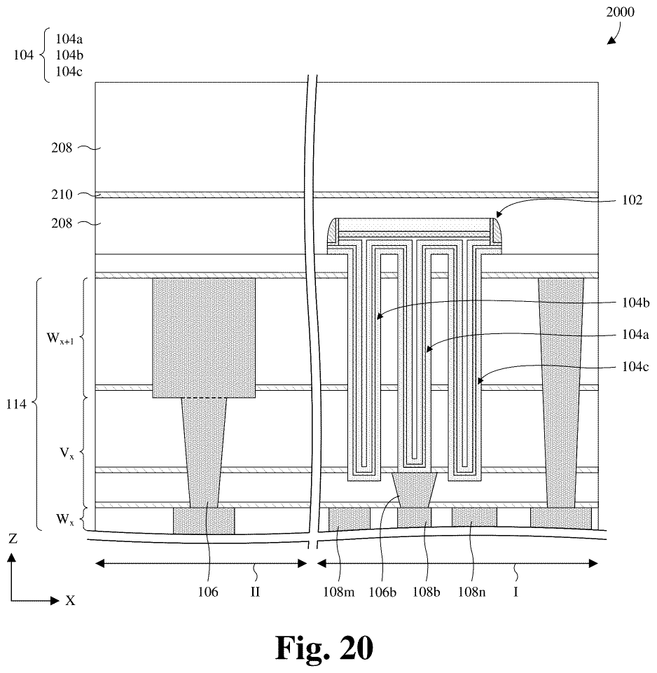

As illustrated by the cross-sectional view 2000 of FIG. 20, a pair of additional IMD layers 208 and an additional etch stop layer 210 are deposited alternatingly and vertically stacked over the capacitor 102. In some embodiments, the pair of additional IMD layers 208 and the additional etch stop layer 210 may collectively be referred to as a third dielectric structure.

One of the pair of additional IMD layers 208 is deposited over and laterally around the capacitor 102, and then the additional etch stop layer 210 is deposited, and then another one of the pair of additional IMD layers 208 is deposited. In some embodiments, a planarization is performed into the one of the pair of additional IMD layers 208 before the depositing of the additional etch stop layer 210 to flatten a top surface of the one of the pair of additional IMD layers 208. The planarization may, for example, be performed by a CMP and/or the like.

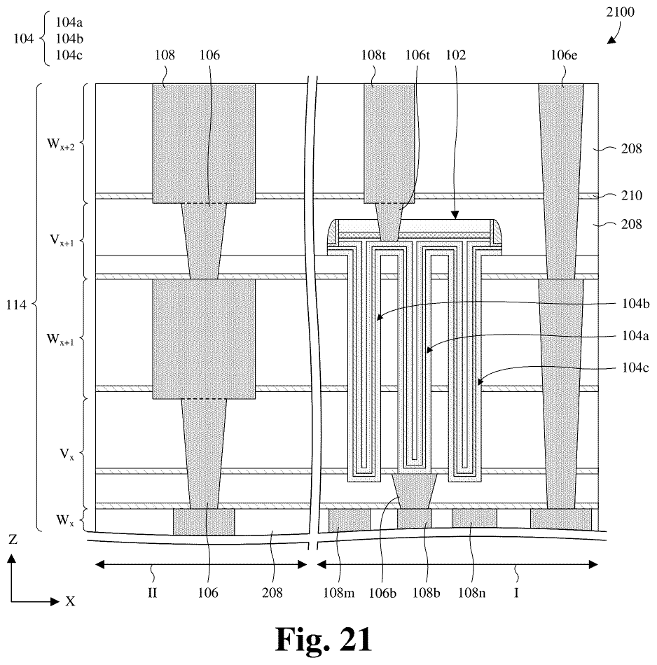

As illustrated by the cross-sectional view 2100 of FIG. 21, a plurality of additional vias 106 and a plurality of additional wires 108 are formed in the pair of additional IMD layers 208 and the additional etch stop layer 210. The plurality of additional vias 106 include an extended via 106 e and a capacitor-top via 106t. Further, the plurality of additional vias 106 are level with each other and form via level Vₓ₊₁ to extend the interconnect structure 114. In some embodiments, the capacitor-top via 106t has a top layout matching a top layout of the capacitor-top via 106t in any of FIGS. 3A-3G. The plurality of additional wires 108 overlie corresponding ones of the plurality of additional vias 106 and include a capacitor-top wire 108t. Further, the plurality of additional wires 108 are level with each other and form wire level Wₓ₊₂ to further extend the interconnect structure 114.

A process for forming the plurality of additional vias 106 and the plurality of additional wires 108 may comprise patterning the additional etch stop layer 210 and the pair of additional IMD layers 208 to form openings corresponding to the plurality of additional vias 106 and the plurality of additional wires 108. Further, the process may comprise filling the openings with a conductive layer and subsequently performing a planarization into the conductive layer to clear the conductive layer from atop the pair of additional IMD layers 208. In other embodiments, the forming may be performed by some other suitable process.

While FIGS. 7-21 are described with reference to a method, it will be appreciated that the structures shown in these figures are not limited to the method but rather may stand alone separate of the method. While FIGS. 7-21 are described as a series of acts, it will be appreciated that the order of the acts may be altered in other embodiments. While FIGS. 7-21 illustrate and describe as a specific set of acts, some acts that are illustrated and/or described may be omitted in other embodiments. Further, acts that are not illustrated and/or described may be included in other embodiments. While FIGS. 7-21 illustrate forming an IC with a capacitor and surrounding structure configured as in FIG. 6, the method may alternatively form an IC with a capacitor and surrounding structure configured as in any one or combination of FIGS. 1, 3A-3G, 4 and 5A-5F.

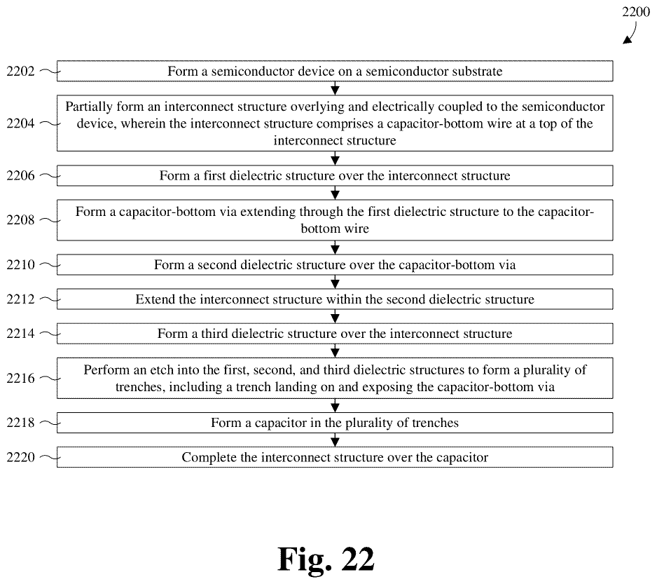

With reference to FIG. 22, a block diagram 2200 of some embodiments of the method of FIGS. 7-21 is provided.

At 2202, a semiconductor device is formed on a semiconductor substrate. See, for example, FIG. 7.

At 2204, an interconnect structure is partially formed overlying and electrically coupled to the semiconductor device, wherein the interconnect structure comprises a capacitor-bottom wire at a top of the interconnect structure. See, for example, FIG. 8.

At 2206, a first dielectric structure is formed over the interconnect structure. See, for example, FIG. 9.

At 2208, a capacitor-bottom via is formed extending through the first dielectric structure to the capacitor-bottom wire. See, for example, FIGS. 10-12.

At 2210, a second dielectric structure is formed over the capacitor-bottom via. See, for example, FIG. 13.

At 2212, the interconnect structure is extended within the second dielectric structure. See, for example, FIG. 14.

At 2214, a third dielectric structure is formed over the interconnect structure. See, for example, FIG. 15.

At 2216, an etch is performed into the first, second, and third dielectric structures to form a plurality of trenches, including a trench landing on and exposing the capacitor-bottom via. See, for example, FIG. 16.

At 2218, a capacitor is formed in the plurality of trenches. See, for example, FIGS. 17-19.

At 2220, the interconnect structure is completed over the capacitor. See, for example, FIGS. 20 and 21.

While the block diagram 2200 of FIG. 22 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

In view of the foregoing, some embodiments of the present application are directed to an IC, including: a substrate; an interconnect structure over the substrate and including a capacitor-bottom wire and a capacitor-bottom via overlying the capacitor-bottom wire; and a capacitor overlying the capacitor-bottom via and including a plurality of trench segments protruding towards the substrate, wherein the plurality of trench segments include a first trench segment and a second trench segment; wherein the capacitor-bottom via extends from the capacitor-bottom wire to the first trench segment, and wherein the second trench segment is spaced from the capacitor-bottom via and a remainder of the interconnect structure. In some embodiments, the second trench segment has a bottom surface that is recessed relative to a top surface of the capacitor-bottom via and that is elevated relative to a top surface of the capacitor-bottom wire. In some embodiments, the interconnect structure further includes an additional wire underlying the second trench segment and at a substantially same elevation as the capacitor-bottom wire, wherein the additional wire is electrically isolated from the capacitor-bottom wire and the second trench segment. In some embodiments, the capacitor includes a bottom electrode, a top electrode, and a dielectric layer that form the plurality of trench segments and that are continuous from the first trench segment to the second trench segment. In some embodiments, the plurality of trench segments include a third trench segment on an opposite side of the first trench segment as the second trench segment, wherein the capacitor-bottom wire has a width that is less than a separation between the second trench segment and the third trench segment. In some embodiments, the IC further includes: a first etch stop layer at a top surface of the capacitor-bottom wire; and a second etch stop layer overlying and spaced from the first etch stop layer and at a top surface of the capacitor-bottom via, wherein a bottom surface of the second trench segment is between and offset from the first etch stop layer and the second etch stop layer in a dimension orthogonal to the top surface of the capacitor-bottom wire. In some embodiments, a top surface of the capacitor-bottom via has a width greater than a width of the first trench segment.

Further, some embodiments of the present application are directed to another IC, including: a substrate; an interconnect structure over the substrate and including a conductive feature; and a capacitor including a bottom electrode, a capacitor dielectric layer, and a top electrode that collectively form a plurality of trench segments, which protrude towards the substrate and which include a first trench segment and a second trench segment; wherein the first trench segment overlies and protrudes to the conductive feature, and wherein the second trench segment is spaced from the conductive feature and has a bottom surface that is recessed relative to a bottom surface of the first trench segment. In some embodiments, a portion of the bottom electrode at the second trench segment is electrically coupled to the interconnect structure with only one conductive path, which passes through the first trench segment. In some embodiments, the first trench segment is at a width-wise center of the capacitor, wherein the second trench segment is at a periphery of the capacitor. In some embodiments, a height of the first trench segment is less than a height of the second trench segment. In some embodiments, the first trench segment and the second trench segment are laterally spaced from each other in a dimension, wherein the conductive feature is recessed into a bottom of the first trench segment in a cross-sectional plane extending laterally traverse to the dimension. In some embodiments, the bottom surface of the second trench segment is elevated relative to a bottom surface of the conductive feature. In some embodiments, the interconnect structure further includes an extended via laterally offset from the capacitor, wherein the extended via has a bottom surface substantially level with a bottom surface of the conductive feature and further has a top surface that is closer to an elevation at a top of the first trench segment than to an elevation at the bottom surface of the first trench segment.

Further, some embodiments of the present application are directed to a method, including: forming a first dielectric structure overlying a capacitor-bottom wire; performing an etch into the first dielectric structure to form a via opening overlying and exposing the capacitor-bottom wire; forming a capacitor-bottom via in the via opening; forming a plurality of dielectric structures stacked over the capacitor-bottom via; performing a second etch into the plurality of dielectric structures to form a plurality of trenches, including a first trench and a second trench, wherein the first trench exposes the capacitor-bottom via and the second trench is spaced from the capacitor-bottom via; depositing a capacitor film overlying the plurality of dielectric structures and lining the plurality of trenches; and patterning the capacitor film to form a capacitor in the plurality of trenches. In some embodiments, a bottom of the second trench is recessed relative to a top of the capacitor-bottom via and is elevated relative to a top of the capacitor-bottom wire at completion of the second etch. In some embodiments, the first dielectric structure is formed overlying an additional wire, which has a top surface level with a top surface of the capacitor-bottom wire, and wherein the second trench is directly over and spaced from the additional wire at competition of the second etch. In some embodiments, the method further includes: forming a second dielectric structure overlying the capacitor-bottom via; forming an additional wire and an additional via in the second dielectric structure, wherein the additional via underlies and extends from the additional wire; and forming a third dielectric structure overlying the additional wire and the second dielectric structure, wherein the second dielectric structure and the third dielectric structure correspond to the plurality of dielectric structures and are etched by the second etch. In some embodiments, a bottom of the second trench is elevated relative to a bottom surface of the additional via, wherein a top of the second trench is elevated relative to a top surface of the additional wire at completion of the second etch. In some embodiments, the capacitor film includes a bottom electrode layer, a capacitor dielectric layer overlying the bottom electrode layer, and a top electrode layer overlying the capacitor dielectric layer, wherein each layer of the capacitor film partially fills the first trench and the second trench and further extends continuously from the first trench to the second trench after formation of the capacitor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC), comprising:
a substrate;
an interconnect structure over the substrate and comprising a capacitor-bottom wire and a capacitor-bottom via overlying the capacitor-bottom wire; and
a capacitor overlying the capacitor-bottom via and comprising a plurality of trench segments protruding towards the substrate, wherein the plurality of trench segments comprise a first trench segment and a second trench segment;
wherein the capacitor-bottom via extends from the capacitor-bottom wire to the first trench segment, and wherein the second trench segment is spaced from the capacitor-bottom via and a remainder of the interconnect structure.

2. The IC according to claim 1, wherein the second trench segment has a bottom surface that is recessed relative to a top surface of the capacitor-bottom via and that is elevated relative to a top surface of the capacitor-bottom wire.

3. The IC according to claim 1, wherein the interconnect structure further comprises an additional wire underlying the second trench segment and at a substantially same elevation as the capacitor-bottom wire, and wherein the additional wire is electrically isolated from the capacitor-bottom wire and the second trench segment.

4. The IC according to claim 1, wherein the capacitor comprises a bottom electrode, a top electrode, and a dielectric layer that form the plurality of trench segments and that are continuous from the first trench segment to the second trench segment.

5. The IC according to claim 1, wherein the plurality of trench segments comprise a third trench segment on an opposite side of the first trench segment as the second trench segment, and wherein the capacitor-bottom wire has a width that is less than a separation between the second trench segment and the third trench segment.

6. The IC according to claim 1, further comprising:
a first etch stop layer at a top surface of the capacitor-bottom wire; and
a second etch stop layer overlying and spaced from the first etch stop layer and at a top surface of the capacitor-bottom via, wherein a bottom surface of the second trench segment is between and offset from the first etch stop layer and the second etch stop layer in a dimension orthogonal to the top surface of the capacitor-bottom wire.

7. The IC according to claim 1, wherein a top surface of the capacitor-bottom via has a width greater than a width of the first trench segment.

8. An integrated circuit (IC), comprising:
a substrate;
an interconnect structure over the substrate and comprising a conductive feature; and
a capacitor comprising a bottom electrode, a capacitor dielectric layer, and a top electrode that collectively form a plurality of trench segments, which protrude towards the substrate and which comprise a first trench segment and a second trench segment;
wherein the first trench segment overlies and protrudes to the conductive feature, and wherein the second trench segment is spaced from the conductive feature and has a bottom surface that is recessed relative to a bottom surface of the first trench segment.

9. The IC according to claim 8, wherein a portion of the bottom electrode at the second trench segment is electrically coupled to the interconnect structure with only one conductive path, which passes through the first trench segment.

10. The IC according to claim 8, wherein the first trench segment is at a width-wise center of the capacitor, and wherein the second trench segment is at a periphery of the capacitor.

11. The IC according to claim 8, wherein a height of the first trench segment is less than a height of the second trench segment.

12. The IC according to claim 8, wherein the first trench segment and the second trench segment are laterally spaced from each other in a dimension, and wherein the conductive feature is recessed into a bottom of the first trench segment in a cross-sectional plane extending laterally traverse to the dimension.

13. The IC according to claim 8, wherein the bottom surface of the second trench segment is elevated relative to a bottom surface of the conductive feature.

14. The IC according to claim 8, wherein the interconnect structure further comprises an extended via laterally offset from the capacitor, wherein the extended via has a bottom surface substantially level with a bottom surface of the conductive feature and further has a top surface that is closer to an elevation at a top of the first trench segment than to an elevation at the bottom surface of the first trench segment.

15. A method, comprising:
forming a first dielectric structure overlying a capacitor-bottom wire;
performing an etch into the first dielectric structure to form a via opening overlying and exposing the capacitor-bottom wire;
forming a capacitor-bottom via in the via opening;
forming a plurality of dielectric structures stacked over the capacitor-bottom via;
performing a second etch into the plurality of dielectric structures to form a plurality of trenches, including a first trench and a second trench, wherein the first trench exposes the capacitor-bottom via and the second trench is spaced from the capacitor-bottom via;
depositing a capacitor film overlying the plurality of dielectric structures and lining the plurality of trenches; and
patterning the capacitor film to form a capacitor in the plurality of trenches.

16. The method according to claim 15, wherein a bottom of the second trench is recessed relative to a top of the capacitor-bottom via and is elevated relative to a top of the capacitor-bottom wire at completion of the second etch.

17. The method according to claim 15, wherein the first dielectric structure is formed overlying an additional wire, which has a top surface level with a top surface of the capacitor-bottom wire, and wherein the second trench is directly over and spaced from the additional wire at competition of the second etch.

18. The method according to claim 15, further comprising:
forming a second dielectric structure overlying the capacitor-bottom via;
forming an additional wire and an additional via in the second dielectric structure, wherein the additional via underlies and extends from the additional wire; and
forming a third dielectric structure overlying the additional wire and the second dielectric structure, wherein the second dielectric structure and the third dielectric structure correspond to the plurality of dielectric structures and are etched by the second etch.

19. The method according to claim 18, wherein a bottom of the second trench is elevated relative to a bottom surface of the additional via, and wherein a top of the second trench is elevated relative to a top surface of the additional wire at completion of the second etch.

20. The method according to claim 15, wherein the capacitor film comprises a bottom electrode layer, a capacitor dielectric layer overlying the bottom electrode layer, and a top electrode layer overlying the capacitor dielectric layer, and wherein each layer of the capacitor film partially fills the first trench and the second trench and further extends continuously from the first trench to the second trench after formation of the capacitor.
